(19) United States
(12) Patent Application Publication
(10) Pub. No.: US 2001/0032708 A1
(43) Pub. Date: Oct. 25, 2001

(54) Electrode plate for plasma etching equipment for forming uniformly-etched surface

(75) Inventors: Akifumi Mishima, Omiya-shi (JP); Toshiharu Hiji, Omiya-shi (JP); Yoshinobu Nakada, Omiya-shi (JP); Tamotsu Mori, Sanda-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Mitsubishi Materials Corporation, Tokyo (JP)

(21) Appl. No.: 09/866,639

(22) Filed: May 30, 2001

Related U.S. Application Data
(63) Continuation of application No. 09/432,274, filed on Nov. 2, 1999.

(30) Foreign Application Priority Data
Nov. 4, 1998 (JP) 10-312704

(51) Int. Cl. H01L 21/3065

(52) U.S. Cl. 156/345

(57) ABSTRACT

An electrode plate which can provide a uniformly-etched surface to an etching surface of a plate to be etched is disclosed, which is used for a plasma etching equipment having such a structure that an electrode plate having a plurality of small vertical through holes is arranged opposite to an etching surface at a prescribed distance from the etching surface, and an etching gas which is introduced into the plasma etching equipment is jetted from the small vertical through holes of the electrode plate and plasma is generated between the etching surface and the surface of the electrode plate to carry out etching, and is characterized in that the electrode plate is composed of high-pure silicon having a cast structure which is formed by a unidirectional solidification perpendicular to the etching surface, thereby to make it possible to form a uniformly-etched surface.

### BACKGROUND OF THE INVENTION

1. Field of the Invention

The present invention relates to an electrode plate for a plasma etching equipment which enables to form a uniformly-etched surface even in case of an enlarged size accompanied by a high integration, when etching is carried out especially for an interlayer-insulating film constituting a semiconductor device.

2. Description of the Related Art

Conventionally, when semiconductor devices are produced, an interlayer-insulating film composed of, for example, silicon oxide (hereinafter, referred to as SiO₂) is deposited on a single crystal silicon wafer by chemical vapor deposition so as to have a prescribed film thickness and then a photoresist film is partially formed thereon and after that, etching is carried out for a part of the interlayer-insulating film as an etching surface on which the photoresist film is not formed.

The partial etching of the interlayer-insulating film is carried out as follows, using a plasma etching equipment illustrated by FIG. 3 showing a brief longitudinal cross section thereof: a plate to be etched which is prepared by forming an interlayer-insulating film and a photoresist film on a single crystal silicon wafer is loaded on a holding plate in the chamber and arranged such that the plate to be etched is in front of and opposite to an electrode plate at a prescribed distance, the electrode plate having a plurality of small vertical through holes; a plate for supplying high-frequency electric power having a plurality of small vertical through holes as well is arranged at the rear of the electrode plate such that each small vertical through hole of the plate for supplying high-frequency electric power lies on the corresponding small vertical through hole of the electrode plate; an etching gas is introduced from the rear of the plate for supplying high-frequency electric power and jetted through the plurality of small vertical through holes of the electrode plate to the etching surface of the plate to be etched together with generating high-frequency plasma between the electrode plate and the etching surface, thereby to carry out the etching. For examples, as disclosed in JP-B 7-40567 and JP-A 5-267235,an electrode plate formed of a single crystal silicon is used for the plasma etching equipments.

Of late years, semiconductor devices have been greatly integrated with the result of a tendency that the diameters of single crystal silicon wafers constituting the semiconductor devices have become larger and larger (larger in sizes). When the above-mentioned conventional plasma etching equipment is used for etching an interlayer-insulating film which is formed on a single crystal silicon wafer having such a larger diameter (a larger size), a decrease in product yield can not be avoided and there is a problem of reliability as an etched surface lack of uniformity is formed with the result that the etched interlayer-insulating film has a dispersing amount of etching in the surface thereof.

### SUMMARY OF THE INVENTION

From the above-mentioned standpoint, the inventors of the present invention have researched, so as to attain a uniform etching of an etching surface having had a larger size, focusing the electrode plate of the plasma etching equipment and obtained the following findings: a uniformity of an etched surface can be more increased by introducing, for the plasma etching equipment, an electrode plate composed of high-pure silicon having a cast structure which is formed by a unidirectional solidification perpendicular to an etching surface as shown in FIG. 1 of a brief perspective view (an electrode plate material of the present invention) in place of the conventional single crystal silicon having no crystal boundary as shown in FIG. 4 of a brief perspective view (the conventional electrode plate material), and the dispersing amount of etching from part to part in an interlayer-insulating film can be hardly admitted, thereby to enable to form a uniformly-etched surface even in case of a single crystal silicon wafer having a larger diameter.

### BRIEF DESCRIPTION OF THE DRAWINGS

FIG. 1 is a brief perspective view illustrating a high-pure silicon having a unidirectional solidification cast structure (the electrode plate material of the present invention), which constitutes the electrode plate of the present invention for a plasma etching equipment.

FIG. 2 is a brief longitudinal cross section view illustrating an equipment for producing a high-pure silicon ingot having a unidirectional solidification cast structure.

FIG. 3 is a brief longitudinal cross section view illustrating a plasma etching equipment.

FIG. 4 is a brief perspective view illustrating a single crystal silicon which constitutes the conventional electrode plate (the conventional electrode plate material) for a plasma etching equipment.

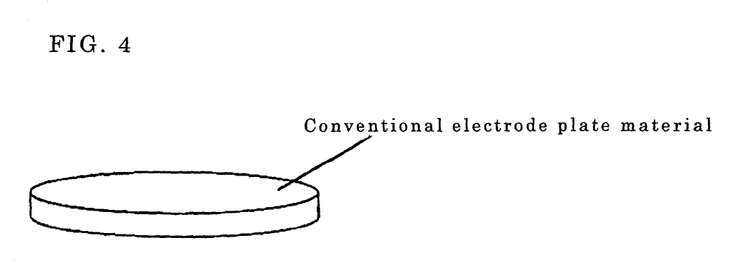

### DESCRIPTION OF PREFERRED EMBODIMENTS

The present invention has been achieved on the above-mentioned findings and is characterized by the following electrode plate for a plasma etching equipment:

the etching equipment has such a structure that an electrode plate having a plurality of small vertical through holes is arranged opposite to an etching surface at a prescribed distance from the etching surface, and an etching gas is jetted from the small vertical through holes of the electrode plate and plasma is generated between the etching surface and the surface of the electrode plate, thereby to carry out etching;

the electrode plate of the present invention is used for the above-mentioned plasma etching equipment and is characterized in that the electrode plate is composed of high-pure silicon having a cast structure which is formed by a unidirectional solidification perpendicular to the etching surface, thereby to make it possible to form a uniformly-etched surface.

The electrode plate of the present invention for the plasma etching equipment is produced by the process comprising the steps of:

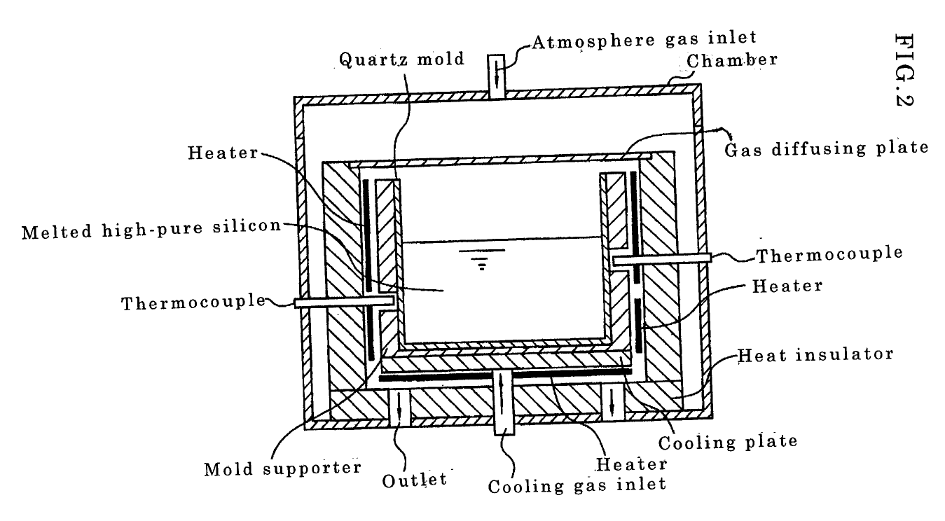

using a melting furnace having a non-oxidizing property, for example, which is illustrated by FIG. 2 showing a brief longitudinal cross section thereof;

first, charging high-pure silicon together with small quantity of a doping material, for example, boron in a quartz mold which is supported by a mold supporter (made of graphite) at the periphery and the bottom;

introducing Ar gas from an atmosphere gas inlet into the chamber and passing the Ar gas through a gas diffusing plate having a lot of small holes (made of graphite) such that an atmosphere for melting is Ar gas;

then, melting the high-pure silicon by a heater (made of graphite) arranged all over between the periphery and the bottom of the mold supporter and a heat insulator (made of graphite) disposed along the mold supporter and at a prescribed distance therefrom;

after melting, measuring temperatures using a plurality of thermocouples arranged around the periphery of the quartz mold at each prescribed depth and, on the basis of the temperature measurements, controlling each heater power at each of the upper part, lower part and the bottom of the mold, respectively;

introducing Ar gas through a cooling gas inlet arranged at the bottom of the chamber and cooling the bottom of the mold through a cooling plate (made of graphite) having a lot of small holes for flowing a gas to form nuclei for solidifying at the bottom of the mold , while controlling each heater power as mentioned-above;

solidifying the melted high-pure silicon in the mold starting from the nuclei, successively from the bottom of the mold toward the upper part of the mold, thereby to form an ingot of high pure silicon having the structure of a unidirectional solidification perpendicular to the bottom of the mold;

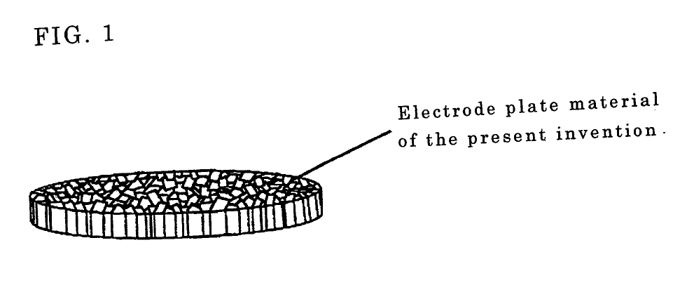

slicing the ingot in a lengthwise direction into electrode plate materials each having a prescribed thickness (the electrode plate material of the present invention illustrated by FIG. 1); and

grinding, drilling, etching, cleaning and polishing the electrode plate materials.

### EXAMPLE

The electrode plate of the present invention for the plasma etching equipment is described in detail with reference to an example hereinafter.

First, the electrode plate of the present invention was produced according to the following process.

Silicon having a purity of 99.9999% and boron having a purity of 99.99% for doping were prepared as raw materials, then the raw materials were charged into the quartz mold arranged in the melting furnace having a non-oxidizing property and melted by heater under Ar gas having a furnace pressure of 6700 Pa which was introduced into the furnace. The melting furnace was kept at 1480-1510° C. which is right over the melting point of silicon by controlling the temperature with thermocouples. After that, the melted high-pure silicon was solidified successively, that is, partially and with the passage of time, at a solidification speed of 1 mm/min. from the bottom of the mold toward the upper part of the mold by cooling the bottom of the mold using Ar gas which was introduced through the cooling plate while controlling each heater power of the bottom, the lower part and the upper part of the mold, thereby to form a high-pure silicon ingot which had the structure of a unidirectional solidification perpendicular to the bottom of the mold, had a dimension of diameter: 380 mm×length: 150 mm and included 100 ppm of boron for doping. Then, the ingot was sliced at a right angle to the lengthwise direction with wire saw to form an electrode plate material (refer to FIG. 1) having a dimension of diameter: 380 mm×thickness: 14 mm and the electrode plate material was ground with surface grinder, drilled with diamond drill and diamond cutting tool, etched by a mixed solution of fluoric acid, nitric acid and acetic acid, and further cleaned by ultra-pure water and polished, thereby to form the electrode plate of the present invention having a dimension of diameter: 365 mm×thickness: 11.2 mm in which small through holes having a diameter of 0.4 mm were formed with a pitch of 5 mm at a center part of within the range of a circle having a diameter of 340 mm and 16 pieces of holes for fixing having a dimension of drilled diameter: 3.5 mm×spot facing diameter: 12 mm×spot facing depth: 6 mm were formed with an equal interval along a circle around the circumference of the through holes, thereby to produce the electrode plate of the present invention.

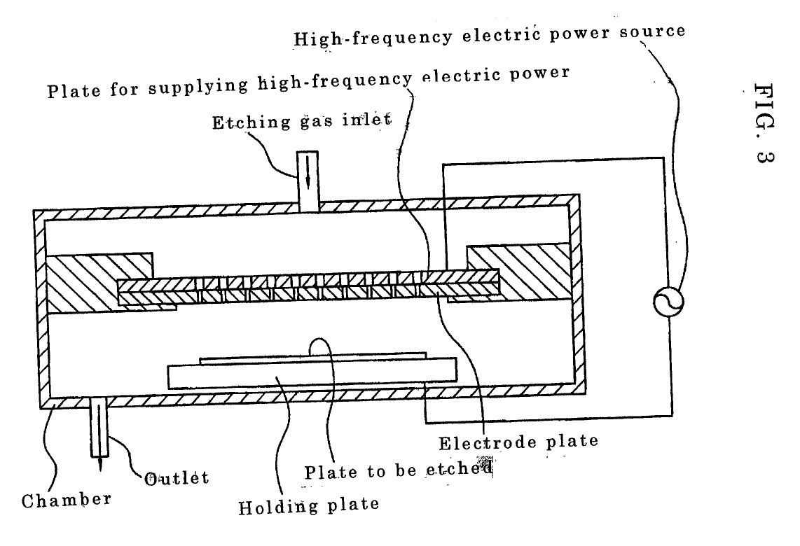

Next, for the purpose of evaluating the performance of the electrode plate of the present invention obtained as mentioned-above and the conventional electrode plate, each of both electrode plates was attached to the plasma etching equipment shown in FIG. 3, while 3 kinds of single crystal silicon wafer each having a diameter of 300 mm, 200 mm and 150 mm were prepared as plates to be etched on the holding plate, wherein the wafer had a SiO₂ film having a thickness of 2 μm formed on a mirror finished surface by a chemical vapor deposition method. With regard to the 3 kinds of single crystal silicon wafer, the SiO₂ films were etched according to the following conditions.

The chamber was evacuated to an atmosphere pressure of 0.05 Pa. Then, an etching gas was introduced into the chamber which comprised CHClF₃, CF₄ and Ar having a ratio of Ar: 300 sccm, CHClF₃: 15 sccm and CF₄: 15 sccm and while holding the atmosphere pressure at 50 Pa, a high-frequency electric power having 1.5 kw was supplied from a high-frequency electric power source to a plate for supplying high frequency electric power, thereby to generate plasma between the electrode plate and the SiO₂ film of the plate to be etched and thereby to carry out etching the SiO₂ film by the generated plasma and the etching gas for 120 sec.

Residual SiO₂ film thickness after the etching treatment was measured at 10 positions (A to J) which comprised points on discretionary diametric lines and points on lines having a right angle to the diametric lines, the points having an equal interval each other. That is, the plate to etched was divided into 4 with regard to the discretionary diametric directions and directions having a right angle to the diametric lines, and each sample was picked from the A to J positions, respectively and the residual SiO₂ film thickness of the samples was measured with transmission electron microscope, the results of which were showed in Table.1.

TABLE 1

| | Diameter of | Residual SiO₂ film thickness (μm) | | | | | | | | | | |
|---|---|---|---|---|---|---|---|---|---|---|---|---|
| | plate to be | Measurement | Measurement position | | | | | | | | | |
| Kind | etched (mm) | direction | A | B | C | D | E | F | G | H | I | J |
| Electrode | 300 | Diametric | 1.03 | 1.03 | 1.02 | 1.02 | 1.02 | 1.02 | 1.02 | 1.03 | 1.03 | 1.03 |
| plate of | | A right angle | 1.03 | 1.03 | 1.03 | 1.02 | 1.02 | 1.02 | 1.02 | 1.03 | 1.03 | 1.03 |
| the present | 200 | Diametric | 1.01 | 1.00 | 1.00 | 1.00 | 1.00 | 1.00 | 1.00 | 1.00 | 1.00 | 1.01 |
| invention | | A right angle | 1.01 | 1.00 | 1.00 | 1.00 | 1.00 | 1.00 | 1.00 | 1.00 | 1.00 | 1.00 |
| | 150 | Diametric | 0.99 | 0.99 | 0.99 | 0.99 | 0.99 | 0.99 | 0.99 | 0.99 | 0.99 | 0.99 |
| | | A right angle | 0.99 | 0.99 | 0.99 | 0.99 | 0.99 | 0.99 | 0.99 | 0.99 | 0.99 | 0.99 |
| Conventional | 300 | Diametric | 1.15 | 1.10 | 1.06 | 1.01 | 0.98 | 0.99 | 1.02 | 1.06 | 1.09 | 1.14 |
| electrode | | A right angle | 1.14 | 1.10 | 1.05 | 1.00 | 0.99 | 0.99 | 1.01 | 1.06 | 1.10 | 1.15 |
| plate | 200 | Diametric | 1.06 | 1.02 | 1.00 | 0.99 | 0.98 | 0.98 | 0.99 | 1.01 | 1.02 | 1.06 |
| | | A right angle | 1.05 | 1.02 | 1.00 | 0.98 | 0.98 | 0.98 | 0.99 | 1.00 | 1.03 | 1.07 |
| | 150 | Diametric | 1.00 | 0.99 | 0.98 | 0.98 | 0.98 | 0.98 | 0.98 | 0.99 | 0.99 | 1.01 |
| | | A right angle | 1.01 | 0.99 | 0.98 | 0.98 | 0.98 | 0.98 | 0.98 | 0.98 | 0.98 | 1.00 |

As is clear from the results shown in Table.1, the electrode plates of the present invention hardly exhibit any change in the residual SiO₂ film thickness between any positions of the surface and the uniformly-etched surfaces can be obtained in the plate to be etched having a diameter of 150 mm as well as even in the plate having a larger diameter of 300 mm, while, in case of the conventional electrode plates, the larger the diameter of the plate to be etched become, the larger dispersion of residual SiO₂ film thickness is caused and the less uniform the etching become and it is difficult to form uniformly-etched surfaces.

As mentioned-above, the electrode plate of the present invention for a plasma etching equipment can satisfactorily cope with the high integration of semiconductor devices, as a uniform etching can be attained all over the etching surface even in case of an etching surface having a larger surface (a larger diameter).

What is claimed is:

1. An electrode plate for a plasma etching equipment comprising:
a plurality of small vertical trough holes;
said electrode plate arranged opposite to an etching surface at a prescribed distance from the etching surface; and
said electrode plate composed of high-pure silicon having a cast structure which is formed by a unidirectional solidification perpendicular to the etching surface, thereby to enable to form a uniformly-etched surface,
wherein an etching gas which is introduced into the plasma etching equipment is jetted from the small vertical through holes of the electrode plate and plasma is generated between the etching surface and the surface of the electrode plate to carry out etching.
